(19) United States
(12) Patent Application Publication
(10) Pub. No.: US 2015/0111322 A1
(43) Pub. Date: Apr. 23, 2015

(54) MANUFACTURING METHOD OF LIGHT-EMITTING STRUCTURE

(71) Applicant: Lextar Electronics Corporation, Hsinchu (TW)

(72) Inventors: Shu-Hong Liu, New Taipei City (TW); Chin-Hao Su, Taipei City (TW); Chi-Chung Chao, Taichung City (TW)

(73) Assignee: Lextar Electronics Corporation, Hsinchu (TW)

(21) Appl. No.: 14/259,175

(22) Filed: Apr. 23, 2014

(30) Foreign Application Priority Data
Oct. 17, 2013 (TW) 102137546

(51) Int. Cl. H01L 33/38

(52) U.S. Cl. CPC H01L 33/382; H01L 2933/0016; H01L 2933/0025
USPC 438/22

(57) ABSTRACT

A manufacturing method of a light-emitting structure is provided. The manufacturing method comprises the following steps. Firstly, a light-emitting die is formed on a carrier substrate carrier substrate, wherein the light-emitting die comprises a first type semiconductor layer, a light-emitting layer and a second type semiconductor layer in order, and has an electrode hole passing through the second type semiconductor layer, the light-emitting layer and a part of the first type semiconductor layer. Next, a current blocking layer covering an inner sidewall of the electrode hole is formed. Then, a current spreading layer covering the current blocking layer is formed, wherein the current spreading layer is separated from the inner sidewall by the current blocking layer. Then, the current blocking layer covering the inner sidewall of the electrode hole is removed.

This application claims the benefit of Taiwan application Serial No. 102137546, filed Oct. 17, 2013, the subject matter of which is incorporated herein by reference.

### BACKGROUND OF THE INVENTION

1. Field of the Invention

The invention relates in general to a manufacturing method of a light-emitting structure, and more particularly to a manufacturing method of a light-emitting structure for resolving the problem of short-circuiting occurring to a semiconductor epitaxial layer.

2. Description of the Related Art

Conventional light-emitting die comprises a first type semiconductor layer, a light-emitting layer and a second type semiconductor layer which are formed on a substrate in order. The light-emitting die has an electrode hole passing through the second type semiconductor layer, the light-emitting layer and a part of the first type semiconductor layer to expose the first type semiconductor layer. However, in a subsequent manufacturing process, since the electrode hole exposes the first type semiconductor layer and the second type semiconductor layer, the first type semiconductor layer and the second type semiconductor layer may easily be electrically bridged to short-circuit by other structure formed subsequently.

### SUMMARY OF THE INVENTION

The invention is directed to a manufacturing method of a light-emitting structure capable of resolving the short-circuiting of the first type semiconductor layer and the second type semiconductor layer.

According to one embodiment of the present invention, a manufacturing method of a light-emitting structure is provided. The manufacturing method comprises the following steps. Firstly, a carrier substrate is provided. Next, a light-emitting die is formed on the carrier substrate, wherein the light-emitting die comprises a first type semiconductor layer, a light-emitting layer and a second type semiconductor layer formed on the carrier substrate in order, and has an electrode hole passing through the second type semiconductor layer, the light-emitting layer and a part of the first type semiconductor layer. The electrode hole has an inner sidewall exposing a lateral surface of each of the first type semiconductor layer, the light-emitting layer and the second type semiconductor layer. Then, a first current blocking layer covering an inner sidewall is formed. Then, a second current blocking layer is formed on the second type semiconductor layer. Then, a current spreading layer covering the first current blocking layer and the second current blocking layer is formed, wherein the current spreading layer is separated from the inner sidewall of the electrode hole by the first current blocking layer. Then, a patterned current spreading layer covering the second current blocking layer is formed. Then, a first current blocking layer covering the inner sidewall of the electrode hole is formed. Then, a first electrode is formed on the first type semiconductor layer exposed the electrode hole. Lastly, a second electrode is formed on the patterned current spreading layer.

According to another embodiment of the present invention, a manufacturing method of a light-emitting structure is provided. The manufacturing method comprises the following steps. Firstly, a carrier substrate is provided. Next, a light-emitting die is formed on the carrier substrate, wherein the light-emitting die comprises a first type semiconductor layer, a light-emitting layer and a second type semiconductor layer formed on the carrier substrate in order, and has an electrode hole passing through a part of the first type semiconductor layer, the light-emitting layer and the second type semiconductor layer and exposing the first type semiconductor layer. The electrode hole has an inner sidewall exposing a lateral surface of each of the first type semiconductor layer, the light-emitting layer and the second type semiconductor layer. Then, a first current blocking layer covering the inner sidewall is formed. Then, a second current blocking layer is formed on an upper surface of the second type semiconductor layer. Then, a current spreading layer covering the first current blocking layer and the second current blocking layer is formed, wherein the current spreading layer is separated from the inner sidewall by the first current blocking layer. Then, a patterned current spreading layer covering the second current blocking layer is formed. Then, a first electrode is formed on the first type semiconductor layer exposed from the electrode hole, wherein the first electrode is separated from the inner sidewall of the electrode hole by the first current blocking layer. Then, a second electrode is formed on patterned current spreading layer exposed from the electrode hole. Lastly, the first current blocking layer covering the inner sidewall of the electrode hole is removed.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIGS. 1A-8 are processes of manufacturing a light-emitting structure according to an embodiment of the invention.

FIGS. 9A-9C are processes of manufacturing a light-emitting structure according to another embodiment of the invention.

FIG. 10 is a cross-sectional view of a light-emitting structure according to of the invention another embodiment.

### DETAILED DESCRIPTION OF THE INVENTION

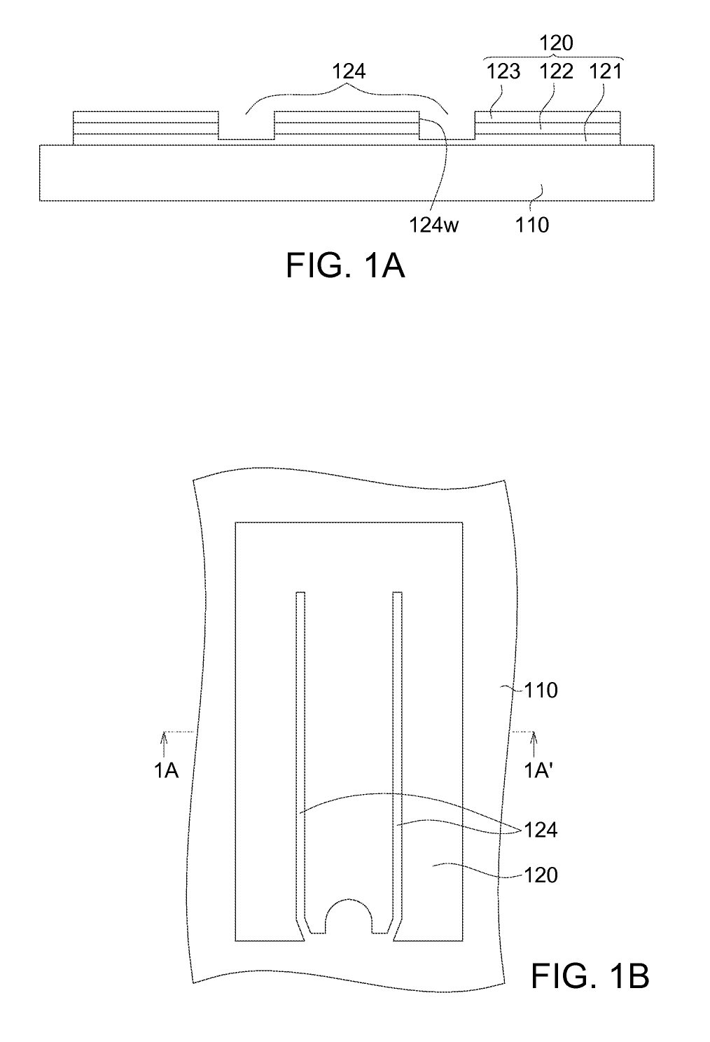

Referring to FIGS. 1A-8, processes of manufacturing a light-emitting structure according to an embodiment of the invention are shown.

As indicated in FIG. 1A and 1B, FIG. 1A is a cross-section view along a direction 1A-1A′ of FIG. 1B. Firstly, a carrier substrate 110 is provided. Next, a light-emitting die 120 is formed on the carrier substrate 110 by using as a deposition process. The light-emitting die 120 comprises a first type semiconductor layer 121, a light-emitting layer 122 and a second type semiconductor layer 123 formed on the carrier substrate 110 in order. The light-emitting die 120 has an electrode hole 124 passing through the second type semiconductor layer 123, the light-emitting layer 122 and a part of the first type semiconductor layer 121. The electrode hole 124 has an inner sidewall 124w exposing a lateral surface of each of the first type semiconductor layer 121, the light-emitting layer 122 and the second type semiconductor layer 123. In other words, an inner lateral surface of the first type semiconductor layer 121, an inner lateral surface of the light-emitting layer 122 and an inner lateral surface of the second type semiconductor layer 123 are exposed from the electrode hole 124 and define the inner sidewall 124w of the electrode hole 124.

The first type semiconductor layer 121 can be realized by a P-type semiconductor layer, and the second type semiconductor layer 123 can be realized by an N-type semiconductor layer. Or, the first type semiconductor layer 121 can be realized by an N-type semiconductor layer, and the second type semiconductor layer 123 can be realized by a P-type semiconductor layer. The P-type semiconductor layer can be realized by a trivalent nitride-based semiconductor layer doped with boron (B), indium (In), gallium (Ga) or aluminum (Al), and the N-type semiconductor layer can be realized by a pentavalent nitride-based semiconductor layer doped with phosphorus (P), antimony (Ti), arsenic (As). The light-emitting layer 122 can be realized by a III-V binary compound semiconductor formed by such as gallium arsenide (GaAs), indium phosphide (InP), gallium phosphide (GaP), gallium nitride (GaN), a III-V multiple compound semiconductor formed by such as aluminum gallium arsenide (AlGaAs), gallium arsenide phosphide (GaAsP), indium gallium aluminum phosphide (AlGaInP), indium gallium aluminum arsenide (AllnGaAs) or a II-VI binary compound semiconductor formed by such as cadmium selenide (CdSe), cadmium sulfide (CdS), zinc selenide (ZnSe).

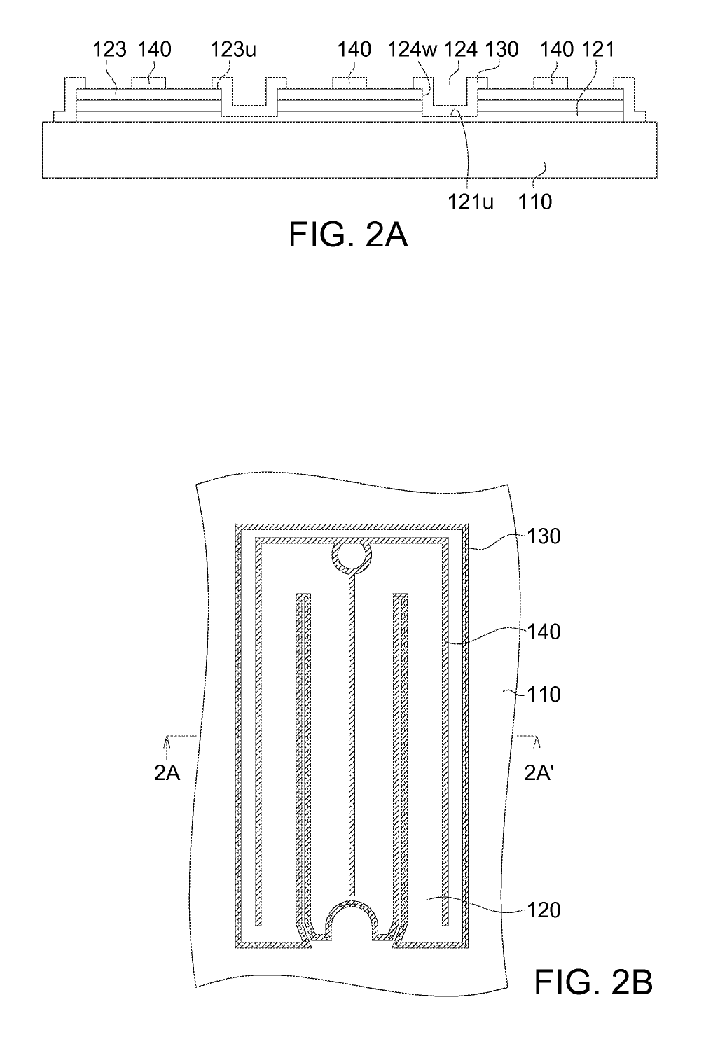

As indicated in FIG. 2A and 2B, FIG. 2A is a cross-section view along a direction 2A-2A′ of FIG. 2B. A first current blocking layer 130 is formed by such as a lithography process (coating/exposure/development). The first current blocking layer 130 covers a part of an upper surface 123u of the second type semiconductor layer 123, the entire inner sidewall 124w of the electrode hole 124, and an upper surface 121 u of the first type semiconductor layer 121 exposed from the electrode hole 124. In the present embodiment, a part of the first current blocking layer 130 covers a part of the upper surface 123u. In another embodiment, the first current blocking layer 130 may not cover the upper surface 123u. The first current blocking layer 130 is a physical blocking layer separating the inner sidewall 124w (comprising the inner lateral surface of the first type semiconductor layer 121, the inner lateral surface of the light-emitting layer 122 and the inner lateral surface of the second type semiconductor layer 123 which are exposed from the electrode hole 124) from a conductive structure formed in a subsequent process to avoid the first type semiconductor layer 121 and the second type semiconductor layer 123 being electrically bridged by the conductive structure and becoming short-circuited.

As indicated in FIGS. 2A and 2B, a second current blocking layer 140 is formed on the upper surface 123u of the second type semiconductor layer 123 by such as a lithography process. Besides, the second current blocking layer 140 and the first current blocking layer 130 can be formed together in the same manufacturing process or separately in different manufacturing processes.

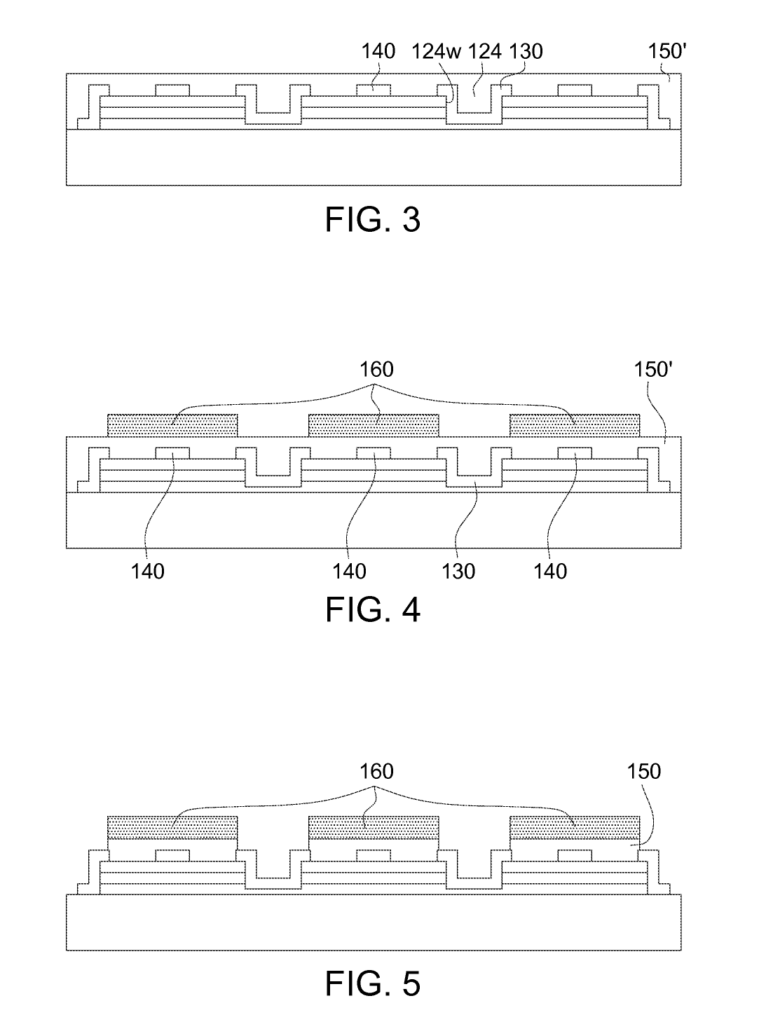

As indicated in FIG. 3, a current spreading layer 150′ entirely covering the first current blocking layer 130 and the second current blocking layer 140 is formed by such as a deposition process. The current spreading layer 150′ is separated from an inner sidewall 124w of the electrode hole 124 by the first current blocking layer 130. Since the current spreading layer 150′ is separated from the inner sidewall 124w of the electrode hole 124, the second type semiconductor layer 123 and the first type semiconductor layer 121 will not be electrically bridged by the current spreading layer 150′ and become short-circuited. In addition, the current spreading layer 150′ is formed by a transparent conductive material such as indium tin oxide (ITO).

As indicated in FIG. 4, a patterned photoresist layer 160 is formed on the current spreading layer 150′ by such as a lithography process. The patterned photoresist layer 160 covers the entire second current blocking layer 140 and a part of the first current blocking layer 130. Since the patterned photoresist layer 160 and the electrode hole 124 do not overlap with each other, the first current blocking layer 130 formed on an inner sidewall 124w of the electrode hole 124 can be removed in a subsequent patterning process.

As indicated in FIG. 5, a current spreading layer 150′ is patterned through the patterned photoresist layer 160 of FIG. 4 and becomes a patterned current spreading layer 150 by such as an etching process. The overlapping part between the current spreading layer 150′ and the patterned photoresist layer 160 is maintained and becomes the patterned current spreading layer 150. The patterned current spreading layer 150 is located right under the second electrode 180 (FIG. 8), such that the range of current distribution is expanded and the range of light output is extended to the two sides of the patterned current spreading layer 150 not covered by the second electrode 180.

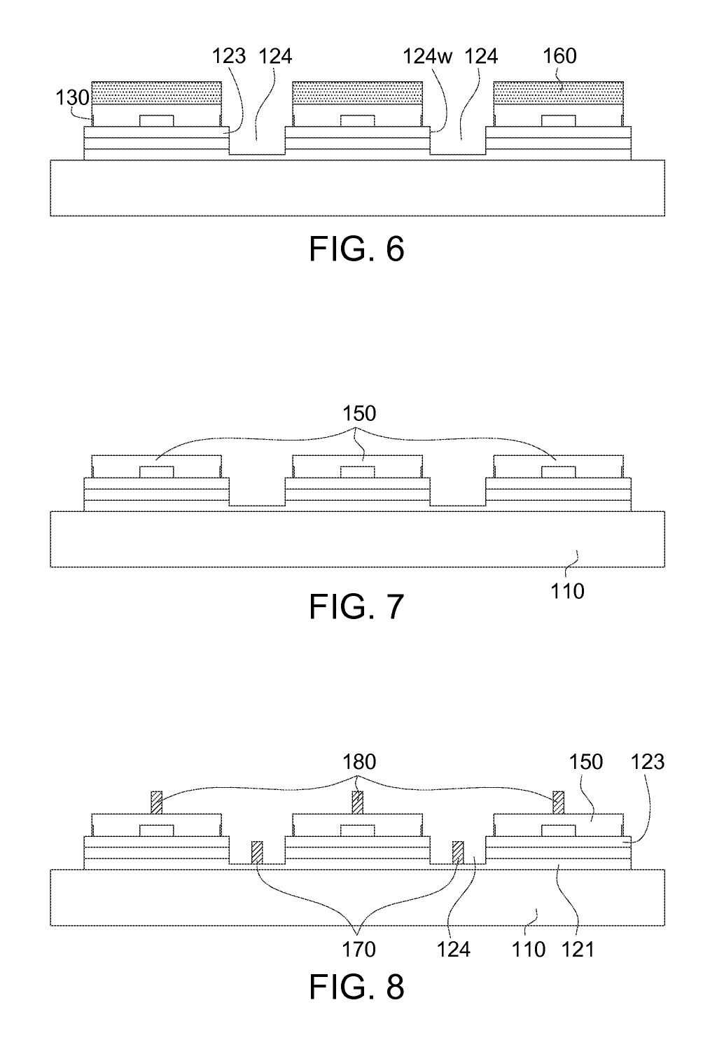

As indicated in FIG. 6, the first current blocking layer 130 covering the inner sidewall 124w of the electrode hole 124 is removed through the same patterned photoresist layer 160 by such as an etching process. Since the same patterned photoresist layer 160 is used, the present step does not need to perform alignment by using a mask again, so that the first current blocking layer 130 covering the inner sidewall 124w of the electrode hole 124 can be completely and accurately removed.

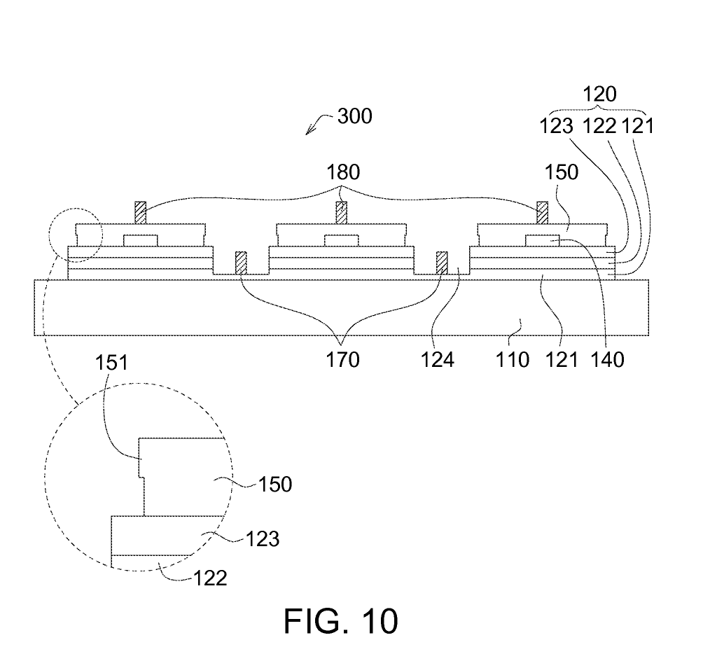

In the present embodiment, a part of the first current blocking layer 130 formed on the second type semiconductor layer 123 is covered by the current spreading layer 150, and is maintained in the etching process. In another embodiment, if the covered part is too thin, the covered part may be removed in the etching process as described in FIG. 10.

Moreover, the step of removing the first current blocking layer 130 covering the inner sidewall 124w of the electrode hole 124 and the step of patterning the current spreading layer 150′ can be finished together in the same manufacturing process or separately in different manufacturing processes.

As indicated in FIG. 7, the patterned photoresist layer 160 of FIG. 6 can be removed by such as an etching process or by way of peeling to expose the patterned current spreading layer 150.

As indicated in FIG. 8, a first electrode 170 is formed on the first type semiconductor layer 121 exposed from the electrode hole 124 by such as a lithography process for electrically connecting the first type semiconductor layer 121.

As indicated in FIG. 8, a second electrode 180 is formed on the patterned current spreading layer 150 by such as a lithography process to form the light-emitting structure 100. The second electrode 180 is electrically connected to the second type semiconductor layer 123 through the patterned current spreading layer 150. Besides, the second electrode 180 and the first electrode 170 can be formed together in the same manufacturing process or separately in different manufacturing processes.

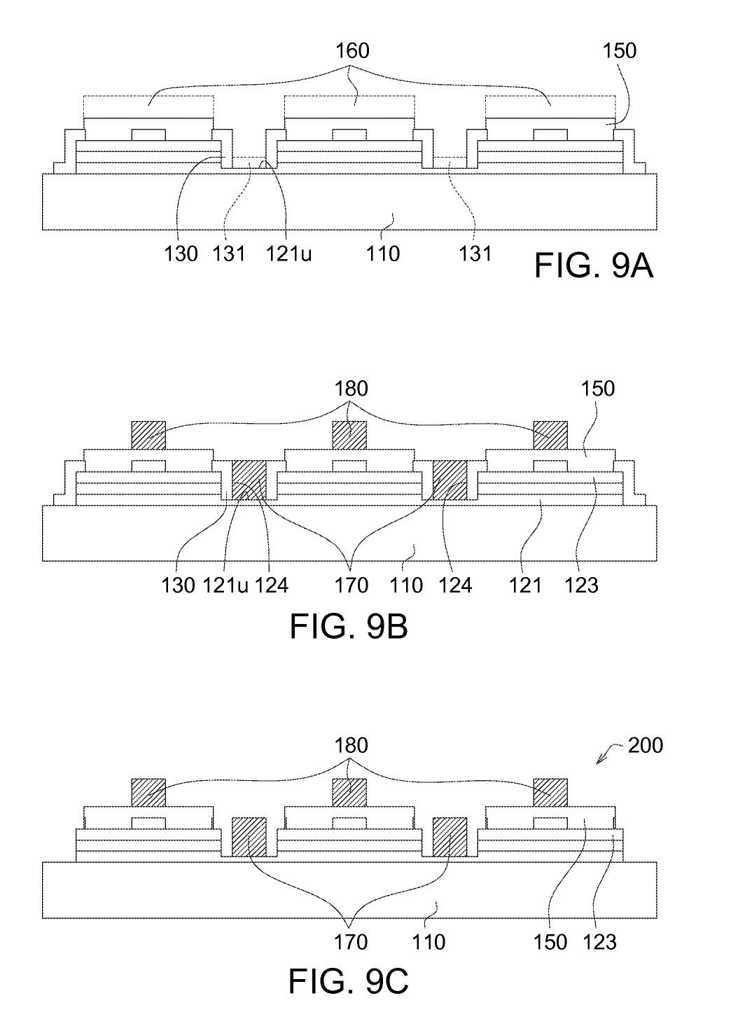

Referring to FIGS. 9A-9C, processes of manufacturing a light-emitting structure according to another embodiment of the invention are shown. Unlike the manufacturing method of a light-emitting structure of disclosed embodiments, the first electrode 170 and/or the second electrode 180 of the light-emitting structure of the present embodiment are formed prior to the step of removing the first current blocking layer 130 covering the inner sidewall 124w of the electrode hole 124.

As indicated in FIG. 9A, following the step of forming the patterned current spreading layer 150 (FIG. 5), the patterned photoresist layer 160 is removed by such as an etching process or by way of peeling to expose the patterned current spreading layer 150.

As indicated in FIG. 9A, a bottom portion 131 of the first current blocking layer 130 is removed by such as an etching process to expose the first type semiconductor layer 121. The bottom portion 131 covered the upper surface 121u of the first type semiconductor layer 121 before the bottom portion 131 is removed.

As indicated in FIG. 9B, the first electrode 170 is formed by such as a lithography process to fill the upper surface 121u of the first type semiconductor layer 121 exposed from the electrode hole 124. The first electrode 170 electrically contacts the first type semiconductor layer 121, but is separated from the inner sidewall 124w (comprising the inner lateral surface of the second type semiconductor layer 123) of the electrode hole 124 through the first current blocking layer 130.

As indicated in FIG. 9B, a second electrode 180 is formed on the patterned current spreading layer 150 by such as a lithography process. The second electrode 180 is electrically connected to the second type semiconductor layer 123 through the patterned current spreading layer 150. Moreover, the second electrode 180 and the first electrode 170 can be formed together in the same manufacturing process or separately in different manufacturing processes.

As indicated in FIG. 9C, the first current blocking layer 130 covering the inner sidewall 124w of the electrode hole 124 can be removed by such as a lithography process to form a light-emitting structure 200.

Referring to FIG. 10, a cross-sectional view of a light-emitting structure 300 according to of the invention another embodiment is shown. The light-emitting structure 300 comprises a carrier substrate 110, a light-emitting die 120, a second current blocking layer 140 and a patterned current spreading layer 150. The light-emitting structure 300 of the present embodiment is different from the light-emitting structure 100 in that the first current blocking layer 130 is removed in the etching step of FIG. 6, such that the patterned current spreading layer 150 forms a suspended projecting structure 151. Although the patterned current spreading layer 150 forms a suspended projecting structure 151, the patterned current spreading layer 150 is still electrically isolated from the light-emitting layer 122 and the first type semiconductor layer 121 of the light-emitting die 120 to avoid the second type semiconductor layer 123 electrically connecting the light-emitting layer 122 or the first type semiconductor layer 121 through the patterned current spreading layer 150.

Besides, the light-emitting structure 200 can also form a projecting structure 151 similar to that of the light-emitting structure 300, and descriptions of similar procedures are not repeated here.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a light-emitting structure, comprising:
providing a carrier substrate;
forming a light-emitting die on the carrier substrate, wherein the light-emitting die comprises a first type semiconductor layer, a light-emitting layer and a second type semiconductor layer formed on the carrier substrate in order, the light-emitting die has an electrode hole passing through the second type semiconductor layer, the light-emitting layer and a part of the first type semiconductor layer, and the electrode hole has an inner sidewall exposing a lateral surface of each of the first type semiconductor layer, the light-emitting layer and the second type semiconductor layer;
forming a first current blocking layer covering the inner sidewall;
forming a second current blocking layer on the second type semiconductor layer;
forming a current spreading layer covering the first current blocking layer and the second current blocking layer, wherein the current spreading layer is separated from the inner sidewall of the electrode hole by the first current blocking layer;
forming a patterned current spreading layer covering the second current blocking layer;
removing the first current blocking layer covering the inner sidewall of the electrode hole;
forming a first electrode on the first type semiconductor layer exposed from the electrode hole; and
forming a second electrode on the patterned current spreading layer.

2. The manufacturing method according to claim 1, wherein the step of forming the patterned current spreading layer and the step of removing the first current blocking layer covering the inner sidewall of the electrode hole comprise:
forming a patterned photoresist layer on the current spreading layer;
patterning the current spreading layer through the patterned photoresist layer to form the patterned current spreading layer, and removing the first current blocking layer covering the inner sidewall of the electrode hole through the same patterned photoresist layer; and
removing the patterned photoresist layer to expose the patterned current spreading layer.

3. The manufacturing method according to claim 1, wherein a part of the first current blocking layer covers an upper surface of the second type semiconductor layer, and the patterned current spreading layer further covers the part of the first current blocking layer.

4. The manufacturing method according to claim 1, wherein the step of forming the first current blocking layer and the step of forming the second current blocking layer are finished in the same manufacturing process.

5. The manufacturing method according to claim 1, wherein in the step of forming the first current blocking layer covering the inner sidewall of the electrode hole, a part of the first current blocking layer covers an upper surface of the second type semiconductor layer; in the step of forming the patterned current spreading layer covering the second current blocking layer, the patterned current spreading layer further covers the part of the first current blocking layer; and the step of removing the first current blocking layer covering the inner sidewall of the electrode hole further comprises:
removing the part of the first current blocking layer covered by the patterned current spreading layer, such that the patterned current spreading layer forms a suspended projecting structure.

6. A manufacturing method of a light-emitting structure, comprising:
providing a carrier substrate;
forming a light-emitting die on the carrier substrate, wherein the light-emitting die comprises a first type semiconductor layer, a light-emitting layer and a second type semiconductor layer formed on the carrier substrate in order, the light-emitting die has an electrode hole passing through a part of the first type semiconductor layer, the light-emitting layer and the second type semiconductor layer and exposing the first type semiconductor layer, and the electrode hole has an inner sidewall exposing a lateral surface of each of the first type semiconductor layer, the light-emitting layer and the second type semiconductor layer;
forming a first current blocking layer covering the inner sidewall;
forming a second current blocking layer on an upper surface of the second type semiconductor layer;
forming a current spreading layer covering the first current blocking layer and the second current blocking layer, wherein the first current blocking layer separates the current spreading layer from the inner sidewall of the electron hole;
forming a patterned current spreading layer covering the second current blocking layer;
forming a first electrode on the first type semiconductor layer exposed from the electrode hole, wherein the first electrode is separated from the inner sidewall of the electrode hole by the first current blocking layer;
forming a second electrode on the patterned current spreading layer exposed from the electrode hole; and
removing the first current blocking layer covering the inner sidewall of the electrode hole.

7. The manufacturing method according to claim 6, further comprising:
forming a patterned photoresist layer on the current spreading layer, and patterning the current spreading layer through the patterned photoresist layer; and
removing the patterned photoresist layer to expose the patterned current spreading layer.

8. The manufacturing method according to claim 6, wherein a part of the first current blocking layer covers the upper surface of the second type semiconductor layer, and the patterned current spreading layer further covers the part of the first current blocking layer.

9. The manufacturing method according to claim 6, wherein the step of forming the first current blocking layer and the step of forming the second current blocking layer are finished in the same manufacturing process.

10. The manufacturing method according to claim 6, wherein prior to the step of forming the first electrode on the first type semiconductor layer exposed from the electrode hole, the manufacturing method further comprises:
removing a bottom portion of the first current blocking layer to expose the first type semiconductor epitaxy.

11. The manufacturing method according to claim 6, wherein in the step forming the first current blocking layer covering the inner sidewall, a part of the first current blocking layer covers the upper surface of the second type semiconductor layer; in the step of forming the patterned current spreading layer covering the second current blocking layer, the patterned current spreading layer further covers the part of the first current blocking layer; and the step of removing the first current blocking layer covering the inner sidewall of the electrode hole further comprises:
removing the part of the first current blocking layer covered by the patterned current spreading layer such that the patterned current spreading layer forms a suspended projecting structure.
